(19) United States
(12) Patent Application Publication
(10) Pub. No.: US 2025/0306100 A1
(43) Pub. Date: Oct. 2, 2025

(54) Undefined State Signaling Injection for Cross Domain Verification

(71) Applicant: Google LLC, Mountain View, CA (US)

(72) Inventors: Anirban Majumder, Bengaluru (IN); Pandithurai Sangaiyah, Bangalore (IN); Thierry Gloude Rajappa, Mountain View, CA (US)

(73) Assignee: Google LLC, Mountain View, CA (US)

(21) Appl. No.: 19/239,039

(22) Filed: Jun. 16, 2025

Related U.S. Application Data
(60) Provisional application No. 63/821,276, filed on Jun. 10, 2025.

(51) Int. Cl. G01R 31/3177

(52) U.S. Cl. CPC G01R 31/3177

(57) ABSTRACT

This document describes systems and techniques directed at verifying, in a test environment, that an undefined digital logic signal is unlikely to cause functional impact on a system-on-chip. In various aspects, clock domain crossing (CDC) and reset domain crossing (RDC) results in an undefined digital value. Various paths through a circuit design that may generate an undefined value (e.g., not a value of zero or a value of one) during testing are identified. A signal injection circuit may be inserted into paths identified as possibly providing an undefined value. The signal injection circuit may be configured to inject an undefined signal into identified paths during testing. The injection of undefined signals within a circuit may simulate signal instability at identified paths. The testing of instability at the identified paths provides thorough analysis, which allows failures to be identified early in the design process.

### CROSS-REFERENCE TO RELATED APPLICATION

This application claims the benefit of U.S. Provisional Patent Application Ser. No. 63/821,276 filed on Jun. 10, 2025, the disclosure of which is incorporated by reference herein in its entirety.

### SUMMARY

This document describes systems and methods, implemented on systems-on-chip (SoC), directed at undefined state signaling injection for cross domain verification. In aspects, the described systems and methods may identify circuitry that crosses different timing domains to test the circuitry by injecting undefined signal states into logic inputs and measuring outputs downstream to check that the undefined signal does not propagate. Different timing domains may include domains of circuitry with different clock timing and/or different reset timing, but may include any type of domain crossing in a SoC circuit. An undefined signal is a signal that may not be conclusively determined to be logic high (1) or logic low (0). The injected undefined signal may simulate metastability in a SoC, which may result from a source signal transitioning close to the sampling edge of a destination flip-flop across different timing domains. The described aspects may enable test bench simulation of failures caused by crossing timing domains. In some cases, the output of a first flip-flop that feeds into the input of a second flip-flop may be disconnected and the input of the second flip-flop may be replaced with the injection of a reference signal or the undefined signal. As such, the undefined signal being fed into the input of the second flip-flop simulates a metastability failure caused by crossing of timing domains.

In some aspects, a method for undefined state signaling injection for cross domain verification includes identifying, on a system-on-chip and by test circuitry, a first flip-flop in a first timing domain having an output signal that feeds into an input signal of a second flip-flop in a second timing domain. The method includes disconnecting the output signal of the first flip-flop in the first timing domain from the input signal of the second flip-flop in the second timing domain. The method further includes modeling a reference signal to replace the output signal of the first flip-flop in the first timing domain. The method further includes identifying instances of the output signal of the first flip-flop in the first timing domain transitioning from a first logic state to a second logic state. The method also includes injecting an undefined signal into the input signal of the second flip-flop in the second timing domain to replace the modeled reference signal. The method also includes measuring one or more downstream signals in the second timing domain to determine that the undefined signal does not propagate through circuitry in the second timing domain. Based on this measuring and determination, the method includes verifying that the injection of the undefined signal into the input signal of the second flip-flop in the second timing domain does not affect the functionality of circuitry in the second timing domain.

The first and second timing domains may have asynchronous clock signals, known as clock domain crossing (CDC). The first and second timing domains may have asynchronous reset signals, known as reset domain crossing (RDC). Prior to the identification of flip-flops that cross different timing domains, the test circuitry may analyze the SoC for instances of timing domain crossing. There are existing formal verification tools specializing in standard X-propagation verification (e.g., Synopsys VC Formal FXP, Siemens Questa Check X, Cadence Jasper X-Prop). The test circuitry may leverage these or other formal verification tools to perform the described operations. In some cases, the method of determining that the undefined signal does not propagate through circuitry in the second timing domain includes probing a primary I/O of a module or sub-block of the second timing domain that includes the second flip-flop. Further in this example, the method of verifying that the injection of the undefined signal into the second flip-flop does not affect the performance of the circuitry in the second timing domain includes verifying that no undefined signal is detected at the primary I/O of a module or sub-block of the second timing domain that includes the second flip-flop.

This document also describes computer-readable media having instructions for performing the above-summarized method and other methods set forth herein, as well as systems and means for performing these methods. In accordance with an aspect of undefined state signaling injection for cross domain verification, there is provided a computer program product configured to be operable to identify time domain crossings, disconnect the circuitry, model a reference signal, identify a logical state transition, inject undefined signals, measure one or more downstream signals, and determine that the undefined signal does not propagate through circuitry downstream to verify that the undefined signal does not affect SoC performance.

This Summary is provided to introduce simplified concepts of undefined state signaling injection for cross domain verification, which are further described below in the Detailed Description and are illustrated in the Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of undefined state signaling injection for cross domain verification are described throughout the disclosure with reference to the Drawings. The use of the same reference numbers in different instances in the Detailed Description and the Drawings indicates same or similar elements:

FIG. 1 illustrates an example operating environment in which aspects of undefined state signaling injection for cross domain verification may be implemented;

FIG. 2 illustrates an example of a timing domain crossing circuit for undefined state signaling injection for cross domain verification;

FIG. 3 illustrates an example timing diagram for undefined state signaling injection for cross domain verification for signals crossing a clock domain;

FIG. 4 illustrates an example method for undefined state signaling injection for cross domain verification for signals crossing a clock domain;

FIG. 5 illustrates an example timing diagram for undefined state signaling injection for cross domain verification for signals crossing a reset domain; and

FIG. 6 illustrates an example method for undefined state signaling injection for cross domain verification for signals crossing a clock domain.

### DETAILED DESCRIPTION

This document describes systems and methods for undefined state signaling injection for cross domain verification. A common challenge in behavioral register transfer level (RTL) simulation testing of SoCs is determining whether crossing a timing domain will cause metastability that negatively impacts the behavior of the SoC design. Metastability occurs when a source signal transitions close to the sampling edge of a destination flip-flop. Such a transition may lead to a sample or hold time violation. A sample time violation may occur if a transition occurs immediately before the sampling edge, and a hold time violation may occur if a transition occurs immediately after the sampling edge. These violations may cause the destination flip-flop output to oscillate and not settle down by the time its output is sampled by any fanout loads downstream in the circuit.

In some implementations of preceding techniques, cross-timing violations may not be reproduced reliably in behavioral RTL simulation testing, so the cross-timing domain violations are usually waived during RTL simulation testing without fully verifying whether ensuing metastability caused by cross-timing domain violations has functional impact on the design. In some implementations, due to preceding challenges in reproducing reliable cross-timing violation behavior during RTL simulation testing, verification of cross-timing domain violation waivers usually occur during post-synthesis gate level simulation (GLS) testing, which may be more capable of reproducing metastability arising out of such cross-timing domain violations. In implementations, GLS simulation level testing may only be performed post-synthesis, which is typically late in the development life cycle of a SoC design. It is more time consuming and, thus, more expensive to fix issues after they are discovered during GLS testing because fixing netlists is complicated and re-synthesis may be a slow process. Additionally, GLS testing may be time-consuming and may have limited scope, preventing the testing from covering corner cases that may be affected by signals crossing different timing domains.

In contrast with the preceding techniques, this disclosure describes aspects of undefined state signaling injection for cross domain verification that may be performed earlier in the development life cycle of SoCs. In various aspects, the methods and systems for undefined state signaling injection for cross domain verification are implemented during RTL simulation testing phase, which is earlier in the development life cycle than the GLS testing phase. As such, the described methods allow for earlier detections of failures that may be caused by metastability when signals cross different timing domains. Earlier detection of these vulnerabilities to metastability saves time in the development of SoCs, and thus, money. That is, aspects of the present disclosure address challenges associated with RTL simulation level testing of the impacts of metastability caused by signals that cross different timing domains.

In aspects, the described systems and methods analyze a SoC to identify instances of timing domain crossing. The system may disconnect the output of a flip-flop in one timing domain from the input of a destination flip-flop in another timing domain. This allows the system to model the original driving signals and inject an undefined signal into the input of the destination flip-flop and simulate metastability at every identified logical state transition. The described aspects of simulating metastability at every identified logical state transition across timing domains in the SoC design provides a more exhaustive test to verify the impact of said metastability during RTL simulation level testing.

This document describes methods and techniques for undefined state signaling injection for cross domain verification, which may be performed earlier in the development of SoCs during RTL simulation testing, allowing developers to save money and time during the design, development, and implementation of SoCs. The following discussion describes an operating environment, example implementations of various test circuitry, and example methods that may be implemented for aspects of undefined state signaling injection for cross domain verification. In the context of the present disclosure, reference is made to the operating environment by way of example only.

### Example Environment

The following discussion describes an operating environment, techniques that may be employed in the operating environment, and various devices or systems in which components of the operating environment may be embodied. In the context of the present disclosure, reference is made to the operating environment by way of example only.

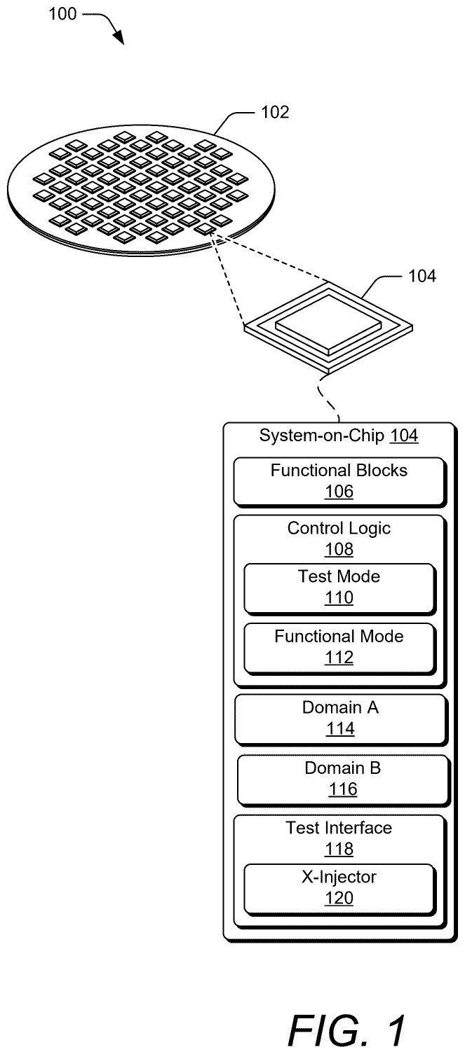

FIG. 1 illustrates an example environment 100 in which aspects of undefined state signaling injection for cross domain verification may be implemented in accordance with one or more aspects. In some aspects, a wafer 102 is fabricated with multiple instances of a system-on-chip 104, integrated circuit, or other type embedded system. As shown in FIG. 1, the wafer 102 includes multiple instances of the system-on-chip 104, which may be configured to enable functionalities of any suitable device. For example, the system-on-chip 104 may be implemented in a smart-phone, a tablet computer, a laptop computer, a gaming console, a desktop computer, a server computer, a wearable computing device (e.g., a smart-watch), a broadband router (e.g., a mobile hotspot), a fixed station, a mobile station, a mobile communication device, a user equipment, an entertainment device, a personal media device, a media playback device, a health monitoring device, a drone, a camera, an Internet home appliance capable of wireless Internet access and browsing, an IoT device, and/or other types of electronic devices.

The system-on-chip 104 includes functional blocks 106, which may include circuitry configured to provide respective functionalities of the system-on-chip 104. The functional blocks 106 may include any suitable type of functional unit, or module, which may include a central processing unit (CPU), graphics processing unit (GPU), digital signal processor (DSP), memory controller, communication interface, security module, encryption block, network-on-chip, neural network engine, audio codec, power management unit, analog-to-digital converters (ADCs), digital-to-analog converters (DACs), or the like. The system-on-chip 104 may also include control logic 108 which may be configured to manage the operating mode of the system-on-chip 104. The control logic 108 may configure the system-on-chip 104 to operate in a test mode 110, which allows the system-on-chip 104 to operate in a testing configuration. Alternatively, the control logic 108 may configure the system-on-chip 104 to operate in a functional mode 112, which allows the system-on-chip 104 to operate according to its functionality.

In aspects, the system-on-chip 104 also includes a domain A 114 and a domain B 116, which are described throughout the disclosure according to various aspects. Domain A 114 and domain B 116 may be configured to operate with asynchronous timing signals. Domain A 114, as described herein, may have a different timing domain as domain B 116. A timing domain refers to a group of circuit elements that are synchronized or otherwise driven by a common timing-related control signal, for example a clock signal, reset signal, or any other timing control signal. Circuitry within timing domains may include one or more logical elements, for example flip-flops, latches, state machines, or any other kind of electronic circuitry. When a signal crosses from domain A to domain B, it is referred to as domain crossing. When a signal crosses timing domains with asynchronous clock signals, it is referred to as clock domain crossing (CDC). When a signal crosses timing domains with asynchronous reset signals, it is referred to as reset domain crossing (RDC).

In aspects, the system-on-chip 104 also includes a test interface 118. Test interface 118 may be configured to facilitate testing, debugging, or validation of internal circuitry of the system-on-chip 104. The test interface 118 may include one or more test modules, for example an x-injector module 120, which may be configured to facilitate injection of undefined signals into destination circuitry of identified timing domain crossings. An undefined signal is a signal that may not be conclusively determined to be logic high (1) or logic low (0). The injected undefined signal may simulate metastability in a SoC, which may result from a source signal transitioning close to the sampling edge of a destination flip-flop across different timing domains. This undefined signal is understood in the art of SoC design as X-propagation. X-propagation refers to the simulation and modeling of undefined, unknown, or indeterminate logic values, commonly represented as ‘X’ as they propagate through digital logic circuits.

In examples, an output signal of domain A 114 feeds into domain B 116 as an input signal, crossing timing domains, thus causing a potential instance for metastability in the circuit. Test interface 118 may be configured to identify the instance of the timing domain crossing, disconnect the output signal of domain A 114 from the input signal of domain B 116, then configure the x-injector module 120 to replace the signal crossing the timing domain with an undefined signal when a logic state transition occurs. In this example, the x-injector module 120 injects the undefined signal into domain B 116 to simulate cross-timing domain metastability in response to a logic state change. Further in this example, the test interface 118 measures an output of circuitry in domain B 116 to determine that undefined signal does not propagate to circuitry in domain B 116, then it may verify that the injection of the undefined signal into domain B 116 does not affect performance of the circuitry in domain B 116.

### Example Devices and Systems

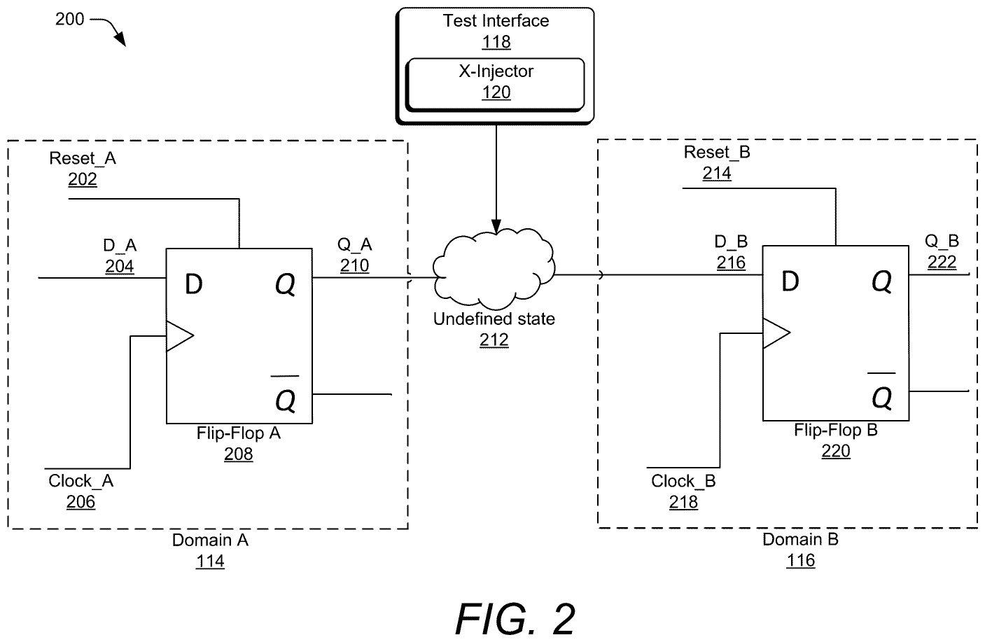

FIG. 2 illustrates an example circuit environment 200 in which aspects of undefined state signaling injection for cross domain verification may be implemented in accordance with one or more aspects. In various aspects, domain A 114 has an output signal Q_A 210 that feeds into an input signal D_B 216 in domain B 116. This timing domain crossing may result in an undefined state 212, which may be an undefined signal state that may cause metastability. Test interface 118 may be configured to identify the signal crossing from domain A 114 to domain B 116 and instruct x-injector module 120 to inject an undefined signal into the input signal D_B 216 in domain B 116 in response to a logic state change by the output signal Q_A 210.

In aspects, domain A includes electronic circuitry (e.g., flip-flop A 208). Flip-flop A 208 may include a reset input signal reset_A 202, a data input signal D_A 204, a clock input signal clock_A 206, and the data output signal Q_A 210. Although illustrated as a D-type flip-flop, the circuitry may alternatively include, but not limited to, flip-flops with different input or output configurations (e.g., JK, T, SR), latches, logic gates, or any other logical element. Flip-flop A 208 may be configured to sample values on the data input signal D_A 204 in response to a triggering edge (e.g., rising edge, falling edge) of clock input signal clock_A 206 and to provide the sampled value on the data output signal Q_A 210. In some implementations, flip-flop A 208 includes a synchronous or asynchronous reset logic, whereby input signal reset_A 202 may be asserted to force output signal Q_A 210 to a predefined state (e.g., logic high, logic low), independently or in conjunction with the clock input signal clock_A 206. Without limitation, flip-flop A 208 may be implemented using logic gates, transistor-level circuitry, or may be abstracted as a logical storage element in a digital design environment.

Further, domain B 116 may include electronic circuitry (e.g., flip-flop B 220). Flip-flop B 220 may include a reset input signal reset_B 214, the data input signal D_B 216, a clock input signal clock_B 218, and a data output signal Q_B 222. Although illustrated as a D-type flip-flop, the circuitry may alternatively include, but not limited to, flip-flops with different input or output configurations (e.g., JK, T, SR), latches, logic gates, or any other logical element. Flip-flop B 220 may be configured to sample values on the data input signal D_B 216 in response to a triggering edge (e.g., rising edge, falling edge) of clock input signal clock_B 218 and to provide the sampled value on the data output signal Q_B 222. In some implementations, flip-flop B 220 includes a synchronous or asynchronous reset logic, whereby input signal reset_B 214 may be asserted to force output signal Q_B 222 to a predefined state (e.g., logic high, logic low), independently or in conjunction with the clock input signal clock_B 218. Without limitation, flip-flop B 220 may be implemented using logic gates, transistor-level circuitry, or may be abstracted as a logical storage element in a digital design environment.

In instances, test interface 118 is configured to analyze the system-on-chip 104 for instances of timing domain crossing. For example, output signal Q_A 210 of flip-flop A 208 in domain A 114 feeds into the input signal D_B 216 of flip-flop B in domain B, which may result in an undefined state 212. Undefined state 212 may be a state of metastability. Metastability occurs when a source signal, Q_A 210 in the example, transitions close to the sampling edge of a destination flip-flop, flip-flip B 220 in the example. Such a transition may lead to a sample or hold time violation. A sample time violation may occur if a transition occurs immediately before the sampling edge, and a hold time violation may occur if a transition occurs immediately after the sampling edge. These violations may cause the destination flip-flop B 220 output Q_B 222 to oscillate and not settle down by the time its output is sampled by any fanout loads downstream in the circuit.

When test interface 118 identifies timing domain crossings as described, it may be configured to disconnect flip-flop A output signal Q_A 210 from the input signal D_B 216 of flip-flip B 220, model the original driving signals with test bench reference signals, then utilize the x-injector module 120 to inject an undefined signal into the input D_B 216 of flip-flop B 220 to simulate metastability in response to a logic state change from flip-flop A output signal Q_A 210. Further in this example, the test interface 118 measures one or more outputs of circuitry in timing domain B 116 to determine that undefined signal injected into the input signal D_B 216 of flip-flop B 220 in domain B 116 does not propagate to circuitry in domain B 116. In the example, based on the determination, the test circuitry 118 may verify that the injection of the undefined signal into D_B 216 of flip-flop B 220 in domain B 116 does not affect performance of the circuitry in domain B 116.

### Example Methods

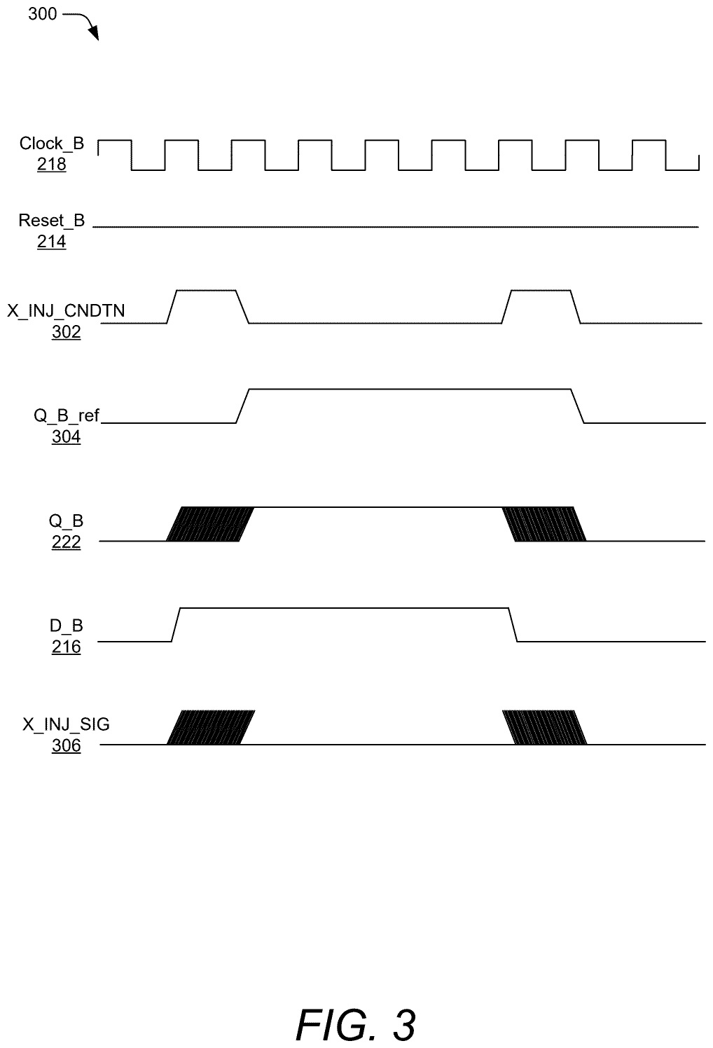

Example timing diagram 300 is described with reference to FIG. 3 in accordance with one or more aspects of undefined state signaling injection for cross domain verification. In portions of the following discussion, reference may be made to the example environment of FIG. 1 and/or the example circuit environment of FIG. 2, reference to which is made for example only. The systems and methods described in this disclosure are not limited to embodiment or performance by one entity or multiple entities operating in relation to undefined state signaling injection for cross domain verification. In aspects, operations of the timing diagram 300 is implemented by or with system-on-chip 104, test interface 118, x-injector 120, domain A 114, domain B 116, flip-flop A 208, and/or flip-flop B 220.

The example timing diagram 300 is an example of signal transitions in one implementation of undefined state signaling injection for cross domain verification. In the example, clock domain crossing (CDC) is demonstrated. Clock input signal clock_B 218 is a periodic clock signal. Reset_B 214 is a reset input signal and shown not to transition in this example. X_INJ_CNDTN 302 is a representation of the x-injection condition within the test interface 118 logic that, when asserted, triggers the test interface 118 to enable the x-injector 120 to inject an undefined signal into flip-flop B 220. In this CDC example, the test interface 118 identifies instances of clock domain crossing, disconnects flip-flop B 220 from flip-flop A 208, substitutes the original driving logic from flip-flop A 208 with a reference signal Q_B_ref 304, and asserts X_INJ_CNDTN 302 to a logic ‘true’ for one or more clock cycles in response to a logic state change by D_B 216. Q_B_ref 304 is a signal representation of a testbench reference signal that models the original driving signal behavior of disconnected flip-flops. The test interface 118 may use Q_B_ref 304 signal to simulate the original behavior of the driving signals that have been disconnected when an undefined signal X_INJ_SIG 306 is not being injected. Output signal Q_B 222 represents an example of an output signal from flip-flop B 220. D_B 216 represents an input signal for flip-flop B 220 that is driven by an output signal of flip-flop A 208 during normal operation of the SoC 104.

In the example timing diagram, the test interface 118 has identified the described signals as crossing a clock timing domain, disconnected flip-flop B 220 from flip-flop A 208, and modeled the input signals with a reference signal Q_B_ref. When input signal D_B 216 transfers from logic low to logic high, this triggers the X_INJ_CNDTN 302 to be true for a clock cycle. Although shown to be asserted for one clock cycle in the illustrated example, test interface 118 may configure X_INJ_CNDTN 302 to be asserted for one or more clock cycles. During the clock cycle while X_INJ_CNDTN 302 is asserted true, the test interface 118 instructs x-injector 120 to inject an undefined signal, represented as X_INJ_SIG 306 in the example timing diagram, into the input of flip-flop B 220. As X_INJ_CNDTN 302 is true and x-injector 120 is injecting undefined signal X_INJ_SIG 306 into flip-flop B 220, the output signal Q_B 222 is shown to reflect the undefined signal source for one clock cycle. One clock cycle after the rising edge of input signal D_B 216 triggers the assertion of X_INJ_CNDTN 302 to become true, output signal Q_B 222 becomes stable.

Further in the example timing diagram, when input signal D_B 216 transfers from logic high to logic low, this once again triggers the X_INJ_CNDTN 302 to be true for a clock cycle. During the clock cycle while X_INJ_CNDTN 302 is asserted true, the test interface 118 instructs x-injector 120 to inject an undefined signal, represented as X_INJ_SIG 306 in the example timing diagram, into the input of flip-flop B 220. As X_INJ_CNDTN 302 is true and x-injector 120 is injecting undefined signal X_INJ_SIG 306 into flip-flop B 220, the output signal Q B 222 is shown to reflect the undefined signal for one clock cycle. One clock cycle after the falling edge of input signal D_B 216 triggers the assertion of X_INJ_CNDTN 302 to become true, output signal Q_B 222 becomes stable.

Test interface 118 may measure the output signal of downstream circuitry in timing domain B 116. If the test interface 118 determines that the undefined signal X_INJ_SIG 306 does not propagate through to output signals of downstream circuitry in timing domain B 116, it verifies that metastability that may be caused from clock timing domain crossing does not affect the performance of circuitry in the second timing domain B 116.

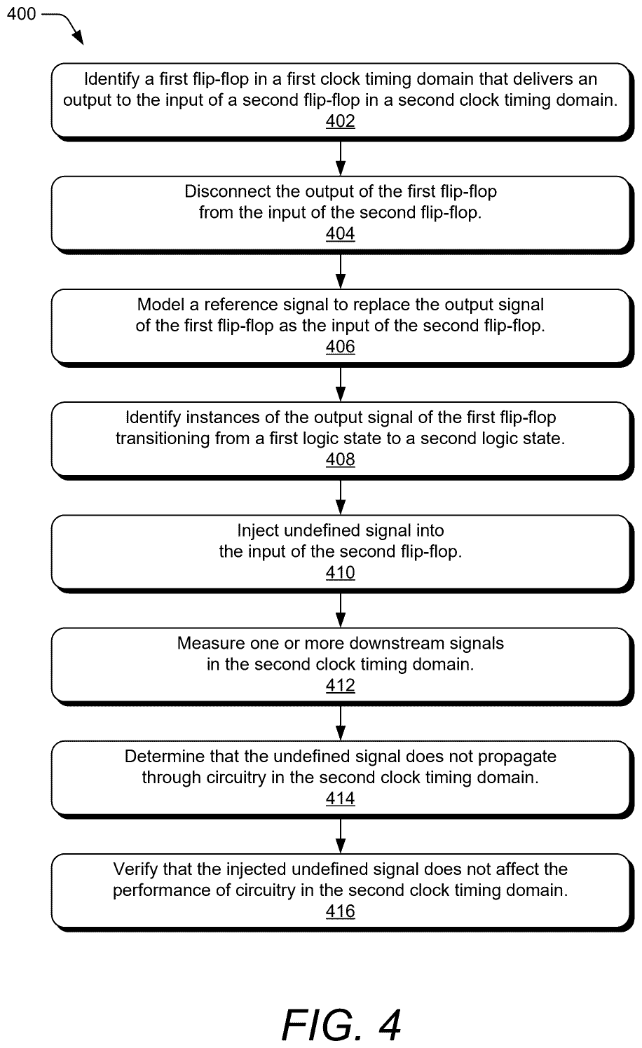

FIG. 4 illustrates an example method 400 for undefined state signaling injection for cross domain verification in accordance with one or more aspects. In aspects, operations of the method 400 are implemented by or with system-on-chip 104, test interface 118, x-injector 120, domain A 114, domain B 116, flip-flop A 208, and/or flip-flop B 220.

Example method 400 is described with reference to FIG. 3 in accordance with one or more aspects of undefined state signaling injection for cross domain verification. Generally, the method 400 illustrates sets of operations (or acts) performed in, but not necessarily limited to, the order or combinations in which the operations are shown herein. Further, any of one or more of the operations may be repeated, combined, reorganized, omitted, or linked to provide a variety of additional and/or alternate methods. In portions of the following discussion, reference may be made to the entities of FIGS. 1-3, reference to which is made for example only. The systems and methods described in this disclosure are not limited to embodiment or performance by one entity or multiple entities operating in relation to undefined state signaling injection for cross domain verification.

At 402, the test interface 118 identifies a first flip-flop in a first clock timing domain that delivers an output to the input of a second flip-flop in a second clock timing domain. For example, the test interface 118 may analyze a SoC circuit for instances of flip-flops having one clock cycle input that feeds a signal into flip-flops having a different clock cycle input. This CDC violation may potentially be a point of failure caused by metastability that may have resulted from the crossing from one clock timing domain to another clock timing domain. By identifying instances of clock domain crossing in the SoC, the test interface 118 is prepared to perform the remaining method operations thoroughly across the SoC and cover potential failure points that would normally be missed by scope limited test methods during the RTL and post-synthesis GLS testing phases.

At 404, the test interface 118 disconnects the output of the first flip-flop from the input of the second flip-flop. In the example, the output from the first flip-flop is no longer driving the input for the second flip-flop. This allows for the output driving signals from the first flip-flop to be replaced without having two signals overlapping each other. With the output from the first flip-flop disconnected from the input for the second flip-flop, the test interface 118 may inject signals into the input of the second flip-flop for testing purposes.

At 406, the test interface 118 models a reference signal to replace the output signal of the first flip-flop as the input of the second flip-flop. In the example, the test interface 118 models the behavior of the output from the first-flip flop as it awaits a logical transition coming from the driving logic of the first flip-flop. This allows the test interface 118 to control the signals going into the input of the second flip-flop without stopping the operation of the second flip-flop as it is disconnected from the driving signals of the first flip-flop.

At 408, the test interface 118 identifies instances of the output signal of the first flip-flop transitioning from a first logic state to a second logic state. In context of the present example, this transition (e.g., from a logic high to a logic low, from logic low to a logic high) is identified to trigger the next operations.

At 410, the test interface 118 injects undefined signals into the input of the second flip-flop. In context of the present example, an undefined, or X-propagation, signal is injected into the input of the second flip-flop to simulate the presence of metastability that may be caused by the identified instance of a logic state transition across different clock timing domains. The test interface 118 may inject an undefined signal at every identified instance of a logic state transition across different clock timing domains to provide thorough coverage, simulating metastability at every identified clock domain crossing in the system-on-chip 104.

At 412, the test interface 118 measures one or more downstream signals in the second clock timing domain. In context of the present example, the measured downstream signal may be an output directly from the second-flip flop, or any output that is downstream in the circuitry of the same timing domain. Usually, the test interface 118 performs this measurement after one or more clock cycles have passed since the injection of the undefined signals.

At 414, the test interface 118 determines that the undefined signal does not propagate through circuitry in the second clock timing domain. In the example, the test interface 118 is determining if the undefined signal injected into the input of the second flip-flop propagates through to any signals downstream in the second clock timing domain. If the undefined signal does not propagate downstream in the second clock timing domain, then it is an indication that the injection of the undefined signal and any ensuing metastability does not affect the performance of the circuitry in the second clock timing domain. In some cases, the method of determining that the undefined signal does not propagate through circuitry in the second timing domain includes probing a primary I/O of a module or sub-block of the second timing domain that includes the second flip-flop.

At 416, the test interface 118 verifies that the injected undefined signal does not affect the performance of circuitry in the second clock timing domain. Concluding the present example, by making the preceding measurement of downstream signals in the second clock timing domain and determining that the injected undefined signal does not propagate through circuitry in the second clock timing domain, the test interface 118 verifies that metastability that may be caused by crossing clock timing domains does not cause propagation of undefined signals downstream that may potentially affect the performance of the SoC design. In some cases, the method of verifying that the injection of the undefined signal into the second flip-flop does not affect the performance of the circuitry in the second timing domain includes verifying that no undefined signal is detected at the primary I/O of a module or sub-block of the second timing domain that includes the second flip-flop.

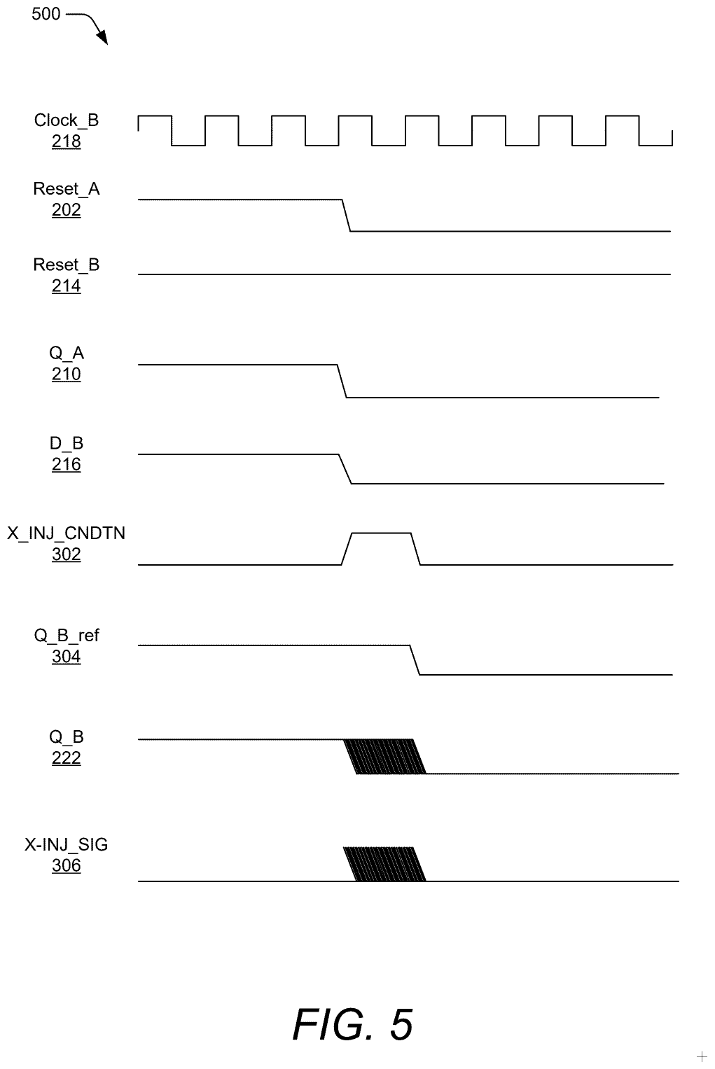

Example timing diagram 500 is described with reference to FIG. 5 in accordance with one or more aspects of undefined state signaling injection for cross domain verification. In portions of the following discussion, reference may be made to the entities of FIGS. 1-4, reference to which is made for example only. The systems and methods described in this disclosure are not limited to embodiment or performance by one entity or multiple entities operating in relation to undefined state signaling injection for cross domain verification. In aspects, operations of the timing diagram 500 is implemented by or with system-on-chip 104, test interface 118, x-injector 120, domain A 114, domain B 116, flip-flop A 208, and/or flip-flop B 220.

The example timing diagram 500 illustrates an example of signal transitions in one implementation of undefined state signaling injection for cross domain verification. In the example, reset domain crossing (RDC) is demonstrated. Clock input signal clock_B 218 is the periodic clock signal. Reset_A 202 is the reset input signal for flip-flop A 208. Reset B 214 is the reset input signal for flip-flop B 220 and shown not to transition in this example. Q_A 210 is the output signal from flip-flop A 208. D_B 216 represents the input signal for flip-flop B 220 and is driven by Q_A 210 during normal operation of the SoC 104. X_INJ_CNDTN 302 is the representation of the x-injection condition within the test interface 118 logic that, when asserted, triggers the test interface 118 to enable the x-injector 120 to inject an undefined signal into flip-flop B 220. In this RDC example, the test interface 118 identifies instances of reset domain crossing, disconnects flip-flop B 220 from flip-flop A 208, substitutes the original driving logic from flip-flop A 208 with a reference signal Q_B_ref 304, and asserts X_INJ_CNDTN 302 to a logic ‘true’ for one or more clock cycles in response to a logic state change by Q_A 210/D_B 216 close to a logic state change by a reset signal. Q_B_ref 304 is the signal representation of the testbench reference signal that models the original behavior of disconnected flip-flops. The test interface 118 may use Q_B_ref 304 signal to simulate the original behavior of the driving signals that have been disconnected when an undefined signal X_INJ_SIG 306 is not being injected. Output signal Q_B 222 represents an example of an output signal from flip-flop B 220. D_B 216 represents both an output signal for flip-flop A 208 and an original driving input signal for flip-flop B 220.

In the example timing diagram, when output signal Q_A 210 drives input signal D B 216 to transfer from logic high to logic low, this triggers the X_INJ_CNDTN 302 to be true for a clock cycle. Although shown to be asserted for one clock cycle in the illustrated example, the X_INJ_CNDTN 302 may be configured to be asserted for one or more clock cycles. During the clock cycle while X_INJ_CNDTN 302 is asserted true, the test interface 118 instructs x-injector 120 to inject an undefined signal, represented as X_INJ_SIG 306 in the example timing diagram, into the input of flip-flop B 220. As X_INJ_CNDTN 302 is true and x-injector 120 is injecting undefined signal X_INJ_SIG 306 into flip-flop B 220, the output signal Q B 222 is shown to reflect the undefined signal for one clock cycle. One clock cycle after the falling edge of input signal D_B 216 triggers the assertion of X_INJ_CNDTN 302 to become true, output signal Q_B 222 becomes stable.

Test interface 118 may measure the output signal of downstream circuitry in timing domain B 116. If the test interface 118 determines that the undefined signal X_INJ_SIG 306 does not propagate through to output signals of downstream circuitry in timing domain B 116, it verifies that metastability that may be caused from reset timing domain crossing does not affect the performance of circuitry in the second timing domain B 116.

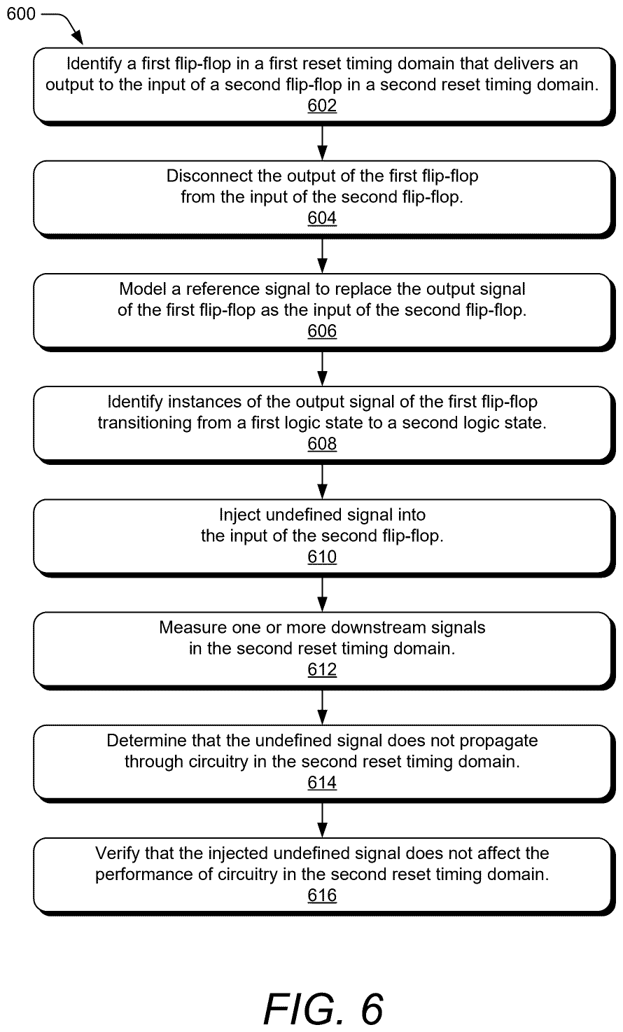

FIG. 6 illustrates an example method 600 for undefined state signaling injection for cross domain verification in accordance with one or more aspects. In aspects, operations of the method 600 are implemented by or with system-on-chip 104, test interface 118, x-injector 120, domain A 114, domain B 116, flip-flop A 208, and/or flip-flop B 220.

Example method 600 is described with reference to FIG. 5 in accordance with one or more aspects of undefined state signaling injection for cross domain verification. Generally, the method 600 illustrates sets of operations (or acts) performed in, but not necessarily limited to, the order or combinations in which the operations are shown herein. Further, any of one or more of the operations may be repeated, combined, reorganized, omitted, or linked to provide a variety of additional and/or alternate methods. In portions of the following discussion, reference may be made to the entities of FIGS. 1-5, reference to which is made for example only. The systems and methods described in this disclosure are not limited to embodiment or performance by one entity or multiple entities operating in relation to undefined state signaling injection for cross domain verification.

At 602, the test interface 118 identifies a first flip-flop in a first reset timing domain that delivers an output to the input of a second flip-flop in a second reset timing domain. For example, the test interface 118 may analyze a SoC circuit for instances of flip-flops having one reset signal input that feeds a signal into flip-flops having a different reset signal input. This RDC violation may potentially be a point of failure caused by metastability that may have resulted from the crossing from one reset timing domain to another reset timing domain. By identifying instances of reset domain crossing in the SoC, the test interface 118 is prepared to perform the remaining method operations thoroughly across the SoC and cover potential failure points that would normally be missed by scope limited test methods during the RTL and post-synthesis GLS testing phases.

At 604, the test interface 118 disconnects the output of the first flip-flop from the input of the second flip-flop. In the example, the output from the first flip-flop is no longer driving the input for the second flip-flop. This allows for the output driving signals from the first flip-flop to be replaced without having two signals overlapping each other. With the output from the first flip-flop disconnected from the input for the second flip-flop, the test interface 118 may inject signals into the input of the second flip-flop for testing purposes.

At 606, the test interface 118 models a reference signal to replace the output signal of the first flip-flop as the input of the second flip-flop. In the example, the test interface 118 models the behavior of the output from the first-flip flop as it awaits a logical transition coming from the driving logic of the first flip-flop. This allows the test interface 118 to control the signals going into the input of the second flip-flop without stopping the operation of the second flip-flop as it is disconnected from the driving signals of the first flip-flop.

At 608, the test interface 118 identifies instances of the output signal of the first flip-flop transitioning from a first logic state to a second logic state. In context of the present example, this transition (e.g., from a logic high to a logic low, from logic low to a logic high) is identified to trigger the next operations.

At 610, the test interface 118 injects undefined signals into the input of the second flip-flop. In context of the present example, an undefined, or X-propagation, signal is injected into the input of the second flip-flop to simulate the presence of metastability that may be caused by the identified instance of a logic state transition across different reset timing domains. The test interface 118 may inject an undefined signal at every identified instance of a logic state transition across different reset timing domains to provide thorough coverage, simulating metastability at every identified reset domain crossing in the system-on-chip 104.

At 612, the test interface 118 measures one or more downstream signals in the second reset timing domain. In context of the present example, the measured downstream signal may be an output directly from the second-flip flop, or any output that is downstream in the circuitry of the same timing domain. Usually, the test interface 118 performs this measurement after one or more clock cycles have passed since the injection of the undefined signals.

At 614, the test interface 118 determines that the undefined signal does not propagate through circuitry in the second reset timing domain. In the example, the test interface 118 is determining if the undefined signal injected into the input of the second flip-flop propagates through to signals downstream in the second reset timing domain. If the undefined signal does not propagate downstream in the second reset timing domain, then it is an indication that the injection of the undefined signal and any ensuing metastability does not affect the performance of the circuitry in the second reset timing domain. In some cases, the method of determining that the undefined signal does not propagate through circuitry in the second timing domain includes probing a primary I/O of a module or sub-block of the second timing domain that includes the second flip-flop.

At 616, the test interface 118 verifies that the injected undefined signal does not affect the performance of circuitry in the second reset timing domain. Concluding the present example, by making the preceding measurement of downstream signals in the second reset timing domain and determining that the injected undefined signal does not propagate through circuitry in the second reset timing domain, the test interface 118 verifies that metastability that may be caused by crossing reset timing domains does not cause propagation of undefined signals downstream that may potentially affect the performance of the SoC design. In some cases, the method of verifying that the injection of the undefined signal into the second flip-flop does not affect the performance of the circuitry in the second timing domain includes verifying that no undefined signal is detected at the primary I/O of a module or sub-block of the second timing domain that includes the second flip-flop.

### CONCLUSION

Although aspects of undefined state signaling injection for cross domain verification has been described in language specific to features and/or methods, the subject of the appended claims is, as recited by any of the previous examples, not necessarily limited to the specific features or methods described. Rather, the specific features and methods are disclosed as example implementations of undefined state signaling injection for cross domain verification, and other equivalent features and methods are intended to be within the scope of the appended claims. Further, various aspects of undefined state signaling injection for cross domain verification are described, and it is to be appreciated that each described aspect may be implemented independently or in connection with one or more other described aspects.

What is claimed is:

1. A method comprising:
identifying, on a system-on-chip and by test circuitry, a first flip-flop in a first timing domain having an output signal that feeds into an input signal of a second flip-flop in a second timing domain;
disconnecting, by the test circuitry, the output signal of the first flip-flop in the first timing domain from the input signal of the second flip-flop in the second timing domain;
modeling, by the test circuitry and based on an original behavior of the output signal of the first flip-flop in the first timing domain, a reference signal to replace the output signal of the first flip-flop in the first timing domain;
identifying, by the test circuitry, instances of the output signal of the first flip-flop in the first timing domain transitioning from a first logic state to a second logic state;
injecting, by the test circuitry and when instances of the output signal of the first flip-flop in the first timing domain transitioning from the first logic state to the second logic state have been identified, an undefined signal into the input signal of the second flip-flop in the second timing domain to replace the modeled reference signal;
measuring, by the test circuitry and one or more clock cycles after the injecting the undefined signal into the input signal of the second flip-flop in the second timing domain, one or more downstream signals in the second timing domain;
determining, by the test circuitry and based on the measuring one or more downstream signals in the second timing domain, that the undefined signal does not propagate through circuitry in the second timing domain; and
verifying, by the test circuitry and based on the determining that undefined signal does not propagate through circuitry in the second timing domain, that the injecting the undefined signal into the input signal of the second flip-flop in the second timing domain does not affect the second timing domain.

2. The method as recited in claim 1, wherein a clock input signal of the first timing domain and a clock input signal of the second timing domain are asynchronous.

3. The method as recited in claim 1, wherein a reset input signal of the first timing domain and a reset input signal of the second timing domain are asynchronous.

4. The method as recited in claim 1, wherein a clock input signal of the first timing domain and a clock input signal of the second timing domain are asynchronous and a reset input signal of the first timing domain and a reset input signal of the second timing domain are asynchronous.

5. The method as recited in claim 1, wherein the operations of claim 1 are conducted as a part of behavioral register transfer level simulation testing.

6. The method as recited in claim 1, wherein the test circuitry uses formal verification tools to perform one or more of the identifying the first flip-flop, the disconnecting, the modeling, the identifying instance of the output signal, the injecting, the measuring, the determining, or the verifying.

7. The method as recited in claim 1, wherein prior to the identifying a first flip-flop in a first timing domain having an output signal that feeds into an input signal of a second flip-flop in a second timing domain:
analyzing, by the test circuitry, the system-on-chip for instances of timing domain crossing.

8. The method as recited in claim 7, wherein the instances of timing domain crossing includes clock domain crossing.

9. The method as recited in claim 7, wherein the instances of timing domain crossing includes reset domain crossing.

10. The method as recited in claim 1, wherein the method of determining that the undefined signal does not propagate through circuitry in the second timing domain includes probing a primary I/O of a module or sub-block of the second timing domain that includes the second flip-flop.

11. The method as recited in claim 10, wherein the method of verifying that the injection of the undefined signal into the second flip-flop does not affect the performance of the circuitry in the second timing domain includes verifying that no undefined signal is detected at the primary I/O of the module or sub-block of the second timing domain that includes the second flip-flop.
